(19) United States
(12) Patent Application Publication
(10) Pub. No.: US 2025/0194191 A1
(43) Pub. Date: Jun. 12, 2025

(54) Power Semiconductor Devices

(71) Applicant: Wolfspeed, Inc., Durham, NC (US)

(72) Inventors: Craig William Hardin, Apex, NC (US); Adam Benjamin Barkley, Chapel Hill, NC (US)

(21) Appl. No.: 18/537,435

(22) Filed: Dec. 12, 2023

(51) Int. Cl. H01L 29/16; H01L 23/00; H01L 29/78; H01L 29/872

(52) U.S. Cl. CPC H10D 62/8325; H01L 24/16; H01L 24/32; H01L 24/73; H10D 8/60; H10D 30/60; H01L 2224/16227; H01L 2224/32225; H01L 2224/73203

(57) ABSTRACT

Power semiconductor devices are provided. In one example, a semiconductor device includes a wide bandgap epitaxial layer. The wide bandgap epitaxial layer includes silicon carbide. The wide bandgap epitaxial layer has a first surface and an opposing second surface. The semiconductor device includes a first contact on the first surface of the wide bandgap epitaxial layer. The second surface is not in direct or indirect contact with a silicon carbide substrate.

### FIELD

The present disclosure relates generally to semiconductor devices, such as wide bandgap semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or gallium nitride (“GaN”) based semiconductor materials.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes a wide bandgap epitaxial layer. The wide bandgap epitaxial layer includes silicon carbide. The wide bandgap epitaxial layer has a first surface and an opposing second surface. The semiconductor device includes a first contact on the first surface of the wide bandgap epitaxial layer. The second surface is not in direct or indirect contact with a silicon carbide substrate.

Another example aspect of the present disclosure is directed to a semiconductor device package. The semiconductor device package includes a wide bandgap epitaxial layer. The wide bandgap epitaxial layer has a first surface and an opposing second surface. The semiconductor device package includes a first contact on the first surface of the wide bandgap epitaxial layer. The first surface of the wide bandgap epitaxial layer is mounted in a flip chip configuration on a submount. The second surface of the wide bandgap epitaxial layer provides at least a portion of a thermal path configured to dissipate heat from the wide bandgap epitaxial layer. The thermal path does not include a semiconductor substrate.

Another example aspect of the present disclosure is directed to a lateral silicon carbide-based transistor device. The transistor device includes an epitaxial silicon carbide layer having a first surface and an opposing second surface. The transistor device includes a drain contact, a source contact, and a gate contact on the first surface of the epitaxial silicon carbide layer. The second surface of the epitaxial silicon carbide layer is free from contact with a silicon carbide substrate.

Another example aspect of the present disclosure is directed to method. The method includes providing a wide bandgap epitaxial layer on a substrate. The wide bandgap epitaxial layer has a first surface and an opposing second surface. The second surface is on the substrate. The method includes providing a contact on the first surface of the wide bandgap epitaxial layer. The method includes placing the first surface of the wide bandgap epitaxial layer on a submount. The method includes removing the substrate from the second surface of the wide bandgap epitaxial layer.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an overview of an example method according to example embodiments of the present disclosure;

FIG. 2 depicts an overview of an example method according to example embodiments of the present disclosure;

FIG. 3 depicts a cross-sectional view of an example lateral power semiconductor device according to example embodiments of the present disclosure;

FIG. 4 depicts a cross-sectional view of an example lateral power semiconductor device according to example embodiments of the present disclosure;

FIG. 5 depicts a plan view of contact layouts on an example lateral power semiconductor device according to example embodiments of the present disclosure;

FIG. 6 depicts a plan view of contact layouts on an example lateral power semiconductor device according to example embodiments of the present disclosure;

FIG. 7 depicts a plan view of contact layouts on an example lateral power semiconductor device according to example embodiments of the present disclosure;

FIG. 8 depicts an overview of an example method according to example embodiments of the present disclosure;

FIG. 9 depicts a cross-sectional view of an example lateral semiconductor device according to example embodiments of the present disclosure;

FIG. 10 depicts an overview of an example method according to example embodiments of the present disclosure;

FIG. 11 depicts a cross-sectional view of an example vertical power semiconductor device according to example embodiments of the present disclosure; and

FIG. 12 depicts a cross-sectional view of an example vertical power semiconductor device according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor layers as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

Power semiconductor devices can have a lateral structure or a vertical structure. In a device having a lateral structure, the terminals of the device (e.g., the drain, gate and source terminals for a power MOSFET device) are on the same major surface (e.g., top surface or bottom surface) of a semiconductor layer. In contrast, in a power semiconductor device having a vertical structure, at least one terminal is provided on each major surface of the semiconductor structure. For instance, in a vertical MOSFET device, the source may be on the top surface of the semiconductor structure and the drain may be on the bottom surface of the semiconductor structure, or vice versa.

Power semiconductor devices are often fabricated by performing fabrication processes on semiconductor wafers. The semiconductor wafers may include one or more epitaxial layers formed on a substrate. As used herein an “epitaxial layer” is a single-crystal semiconductor layer grown on top of a substrate using a process called epitaxial growth or epitaxy. The epitaxial layer may be deposited atom by atom and may adopt the crystal structure of the underlying substrate. An epitaxial layer may have a thickness in a range of, for instance, about 0.2 microns to about 200 microns.

A “substrate” refers to a solid semiconductor material upon which epitaxial layers are formed. A substrate may be a homogenous material, such as silicon carbide and/or sapphire and may provide mechanical support for the formation of epitaxial layers. In many examples, substrates may be provided as a semiconductor wafer on which various other layers and structures are formed. A substrate may have a thickness in a range of about 0.5 microns to about 1000 microns, or greater.

Power semiconductor devices (e.g., MOSFETs, JFETs, Schottky diodes, HEMTs) may be fabricated on a silicon carbide (e.g., 4H polytype) semiconductor wafer where the monocrystalline silicon carbide wafer serves as a substrate for the power semiconductor device. A significant portion of the silicon carbide substrate (e.g., monocrystalline silicon carbide substrate) may remain as part of the power semiconductor device, even after backside grinding to final wafer thickness. Many power semiconductor devices are vertical power devices and may conduct current through the substrate. As a result, the silicon carbide substrate may, in some cases, add significant series resistance to the power semiconductor device and may add conduction losses to end application circuits for the power semiconductor device.

Aspects of the present disclosure are directed to power semiconductor devices that reduce and/or eliminate a silicon carbide substrate from the power semiconductor devices. More particularly, one or more power semiconductor devices may be fabricated in a wide bandgap epitaxial layer provided on a substrate (e.g., a semiconductor wafer). The substrate may be, for instance, a silicon carbide substrate (e.g., 4H monocrystalline silicon carbide) or other substrate, such as a sapphire substrate or a silicon substrate. The semiconductor wafer may undergo, for instance, wafer level processing to mount one or more semiconductor die to a submount. The semiconductor die may include one or more semiconductor devices fabricated in the wide bandgap epitaxial layer. In some examples, the semiconductor wafer may be “flipped” and mounted on submount structures so that each of a plurality of semiconductor die on the semiconductor wafer are mounted to one of a plurality of submounts (e.g., lead frames, clip structures, power substrates, DBC substrates, AMB substrates, etc.).

According to example embodiments of the present disclosure, a backside of the semiconductor wafer, including the substrate may be removed from the epitaxial wide bandgap semiconductor structure. One example removal process may include inducing a cleavage plane in the wide bandgap epitaxial layer and removing the first substrate from the wide bandgap epitaxial layer along the cleavage plane. Inducing the cleavage plan may include emitting one or more lasers into the wide bandgap epitaxial layer. Example techniques for inducing a cleavage plane using one or more lasers are disclosed in U.S. Pat. Nos. 10,576,585, 10,562,120, which are incorporated herein by reference. Other suitable techniques may be used to induce the cleavage plane without deviating from the scope of the present disclosure, such as implanting one or more species into the wide bandgap epitaxial layer.

Other suitable removal process(s) may be used without deviating from the scope of the present disclosure. For instance, chemical mechanical polish (CMP) process(s), grinding process(s), etc. may be used to remove the substrate from the epitaxial wide bandgap semiconductor structure. In some embodiments, an etching process may be used to remove the substrate.

The semiconductor wafer may be subjected to further wafer level processing and singulated to form individual semiconductor device packages. The individual semiconductor device packages may include one or more semiconductor die mounted in a flip chip configuration on a submount. The individual semiconductor device packages may not include a silicon carbide substrate. For instance, the wide bandgap epitaxial layer may not be in direct or indirect contact with a silicon carbide substrate. In this way, there may be no silicon carbide substrate in a thermal path configured to dissipate heat from the wide bandgap epitaxial layer.

Aspects of the present disclosure are discussed with wafer level processing for purposes of illustration and discussion. Those of ordinary skill in the art, using the disclosures provided herein, will understand that wafer level processing is not required. For instance, individual semiconductor die (after being singulated or diced from a wafer) may be flipped and mounted to a submount in a flip chip configuration. The backside of the semiconductor die may undergo a removal process to remove a substrate from the wide bandgap epitaxial layer.

Example aspects of the present disclosure may be used to provide lateral power semiconductor devices and/or vertical power semiconductor devices. In some examples, a lateral silicon carbide-based transistor device may include an epitaxial silicon carbide layer having a first surface and an opposing second surface. The transistor device may include a drain contact, a source contact, and a gate contact on the first surface of the epitaxial silicon carbide layer such that the transistor device is a lateral device. The second surface of the epitaxial silicon carbide layer may be free from contact with a silicon carbide substrate. In some examples, the second surface of the epitaxial silicon carbide layer provides at least a portion of a thermal path for dissipation of heat from the epitaxial silicon carbide layer. The thermal path does not include a silicon carbide substrate.

In some examples, the epitaxial silicon carbide layer is on a sapphire substrate. In some examples, the epitaxial silicon carbide layer is on a silicon substrate. In some examples, there is no semiconductor substrate.

In some examples, the epitaxial silicon carbide layer is mounted in a flip chip configuration in a semiconductor device package. The insulating material (e.g., epoxy mold compound) of the semiconductor package may be directly on the second surface of the epitaxial silicon carbide layer. An underfill material may be on the epitaxial silicon carbide layer to increase creepage between the source contact and the drain contact. The underfill material may be on the gate contact. The underfill material may be an organic material, such as a composite epoxy material.

In some examples, the lateral transistor device is a MOSFET. The epitaxial silicon carbide layer may include a drift region having a first conductivity type. At least a portion of the drift region is between the source contact and the drain contact. The epitaxial silicon carbide layer may include a well region of a second conductivity type. The well region may be between the drift region and the source contact. In some examples, the epitaxial silicon carbide layer comprises a source region of the first conductivity type proximate to the source contact, and a drain region of the first conductivity type proximate to the drain contact. In some examples, the source contact and the drain contact are each ohmic contacts with the epitaxial silicon carbide layer. In some examples, the transistor device includes gate dielectric between the gate contact and the epitaxial silicon carbide layer.

The source contact, the drain contact, and the gate contact may be provided in various patterns on the first surface of the epitaxial silicon carbide layer. For instance, in some examples, the drain contact is at least partially interdigitated with the source contact. In some examples, the drain contact includes a plurality of intersecting drain buses forming a grid. The source contact includes a plurality of source contacts within spaces in the grid. The gate contact includes a plurality of gate contacts. Each gate contact at least partially surrounds one of the plurality of source contacts.

Aspects of the present disclosure may also include vertical power semiconductor devices. For instance, the semiconductor device has a first contact on the first surface of the wide bandgap epitaxial layer. The semiconductor device has a second contact on the second surface of the wide bandgap epitaxial layer such that the semiconductor device is a vertical power semiconductor device. In some examples, there is no silicon carbide substrate between the wide bandgap epitaxial layer and the second contact. For instance, there may be a sapphire substrate or silicon substrate between the wide bandgap epitaxial layer and the second contact. In some examples, there is no substrate between the wide bandgap epitaxial layer and the second contact.

Aspects of the present disclosure provide a number of technical effects and benefits. For instance, aspects of the present disclosure may provide power semiconductor devices without a bulk silicon carbide substrate. This may reduce bulk resistivity, for instance, in vertical power devices and may lead to improved thermal performance by providing a thermal path that does not include a silicon carbide substrate. In some cases, various patterns of contacts may be implemented, for instance, on a surface of the wide bandgap semiconductor structure to provide enhanced flexibility in semiconductor device packaging. More particularly, the contact may be arranged in different patterns as needed to facilitate making connections to submounts and other structures in semiconductor device packages.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

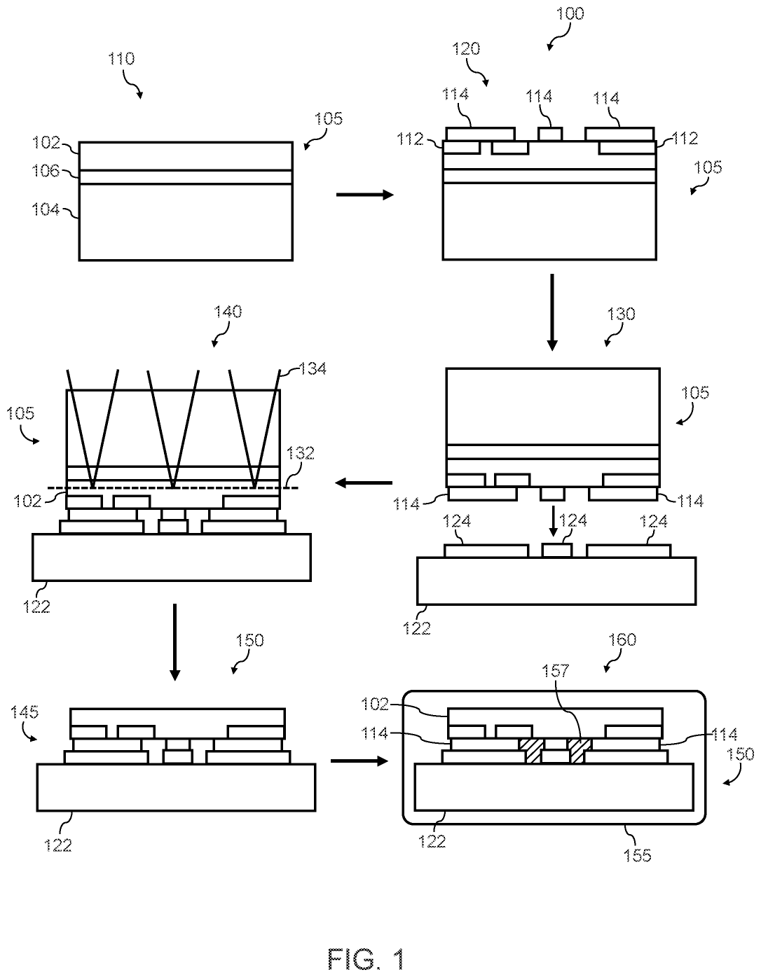

FIG. 1 depicts an overview of an example method 100 according to example embodiments of the present disclosure. FIG. 1 is intended to represent structures for identification and description and is not intended to represent the structures to physical scale. The method 100 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 110, the method may include providing a wide bandgap epitaxial layer 102 on a substrate 104. The substrate 104 may be a silicon carbide substrate (e.g., 4H monocrystalline silicon carbide), sapphire substrate, or silicon substrate in some examples. Other suitable substrates may be used as the substrate 104 without deviating from the scope of the present disclosure. The substrate 104 may be in the form of a semiconductor wafer 105. In some examples, the substrate 104 has a thickness in a range of about 100 μm to about 1000 μm.

The wide bandgap epitaxial layer 102 may be formed by epitaxial growth. The wide bandgap epitaxial layer 102 may be, in some embodiments, an epitaxial silicon carbide layer. The wide bandgap epitaxial layer 102 may be, in some embodiments, an epitaxial Group III-nitride layer. The wide bandgap epitaxial layer 102 may be formed using any suitable epitaxial growth process, such as hybrid vapor phase epitaxy (HVPE), metal-organic vapor phase epitaxy (MOVPE), molecular beam epitaxy (MBE), or other suitable growth process. The wide bandgap epitaxial layer 102 may have a thickness in a range of about 0.2 μm to about 200 μm, such as about 0.5 μm to about 100 μm, such as about 0.5 μm to about 20 μm.

In some examples, the substrate 104 may include a buffer layer 106. The buffer layer may be an epitaxial layer. The buffer layer 106 may be formed by epitaxial growth on the substrate 104. The buffer layer 106 may be used to mitigate a lattice mismatch between, for instance, the substrate 104 (e.g., sapphire substrate) and the wide bandgap epitaxial layer 102. In some embodiments, the buffer layer 106 may be a Group III-nitride, such as aluminum nitride.

The method 100 may include at 120 fabricating one or more semiconductor device structures (e.g., transistor structures, Schottky diode structures, etc.) at least in part in the wide bandgap epitaxial layer 102. More particularly, one or more semiconductor device structures (e.g., MOSFETs, Schottky diodes, HEMTs) may be fabricated in the wide bandgap epitaxial layer.

For purposes of illustration and discussion, fabricating one or more semiconductor device structures may include forming one or more doped regions 112 in the wide bandgap epitaxial layer 102. The one or more doped regions 112 may include regions of a first conductivity type (e.g., n-type) and may include regions of a second conductivity type (e.g., p-type). In some embodiments, the one or more doped regions may be formed, for instance, by dopant implantation. In some embodiments, the one or more doped regions may be formed, for instance, as part of epitaxial growth of the wide bandgap epitaxial layer 102.

Fabricating one or more semiconductor device structures may include forming one or more contacts 114 (e.g., metal contacts) on the wide bandgap epitaxial layer 102. For instance, polysilicon and/or metal deposition techniques may be used to form patterned contacts 114 on the wide bandgap epitaxial layer 102. The contacts 114 may include, in some embodiments, a source contact, a drain contact, and a gate contact on the surface of the wide bandgap epitaxial layer 102. The contacts 114 may include, for instance, solder bumps, contact pads, or other interconnect structures on the wide bandgap epitaxial layer 102.

Fabricating one or more semiconductor device structures may include other fabrication steps, such as deposition steps, etching steps, metallization steps, etc. The description of the fabrication process has been simplified in this discussion of FIG. 1 for purposes of illustration and discussion. Those of ordinary skill in the art, using the disclosures provided herein, will understand that any suitable fabrication process(s) may be used to form semiconductor device structures in the wide bandgap epitaxial layer 102 without deviating from the scope of the present disclosure.

Referring to FIG. 1, the method 100 at 130 may include “flipping” the semiconductor wafer 105 and attaching the semiconductor wafer 105 to submount(s) 122. The submount 122 may include, for instance, a lead frame(s), a heat sink(s), clip structure(s), DBC substrate(s), or other suitable submount(s). The contacts 114 may be attached to metal structures 124 (e.g., pads) on the submount(s) to provide thermal and/or electrical connections to the contacts 114. In some embodiments, a die-attach material may be used to attach the wafer 105 to the submount(s) 122.

Referring to FIG. 1 at 140, the method 100 may include removing the substrate 104 (e.g., the sapphire substrate) from the wide bandgap epitaxial layer 102. One example removal process may include inducing a cleavage plane 132 in the wide bandgap epitaxial layer 102 and removing the substrate 104 from the wide bandgap epitaxial layer 102 along the cleavage plane 132. Inducing the cleavage plane 132 may include emitting one or more lasers 134 into the wide bandgap epitaxial layer 102 to induce damaged regions along the cleavage plane 132. Other suitable techniques may be used to induce the cleavage plane 132 without deviating from the scope of the present disclosure, such as implanting one or more species into the wide bandgap epitaxial layer 102.

Once the substrate 104 has been removed from the wide bandgap epitaxial layer 102, the method 100 at 150 yields an assembly 145 with semiconductor die (without a substrate) including the wide bandgap epitaxial layer 102 attached to the submount(s) 122. The assembly 145 may be singulated or diced and processed to form individual semiconductor device packages including one or more semiconductor die.

For instance, at 160, the method 100 may include providing an insulating material 155 on the wide bandgap epitaxial layer 102 and the submount 122 to form a power semiconductor device package 150. The insulating material 155 may be an epoxy mold compound. The method 100 may further include providing an underfill material 157 on the contacts 114. The underfill material 157 may be, for instance, a composite material made up of a polymer (e.g., epoxy polymer) with filler and/or additional components. The underfill material 157 may increase creepage between, for instance, a source contact and a gate contact for the power semiconductor package 150. The power semiconductor device package 150 may be a discrete power semiconductor package. However, in some embodiments, the power semiconductor device package may be, for instance, a power module.

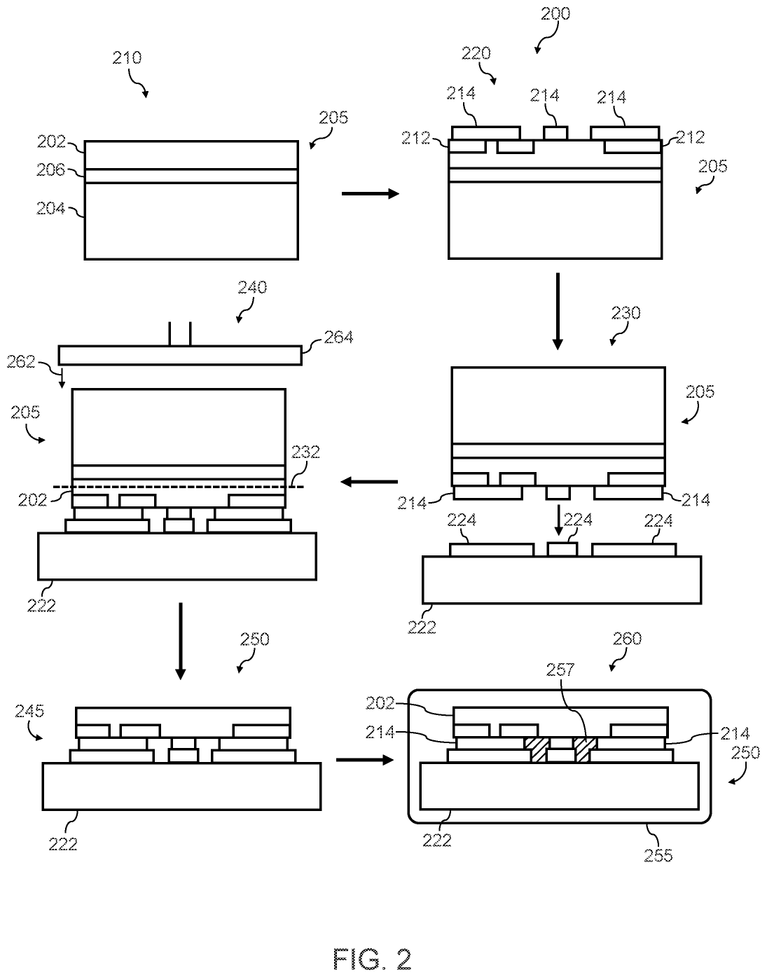

FIG. 2 depicts an overview of an example method 200 according to example embodiments of the present disclosure. FIG. 2 is intended to represent structures for identification and description and is not intended to represent the structures to physical scale. The method 200 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

The method 200 of FIG. 2 is similar to the method 100 of FIG. 1. More particularly, At 210, the method may include providing a wide bandgap epitaxial layer 202 on a substrate 204. The substrate 204 may be a silicon carbide substrate (e.g., 4H monocrystalline silicon carbide), sapphire substrate, or silicon substrate in some examples. Other suitable substrates may be used as the substrate 204 without deviating from the scope of the present disclosure. The substrate 204 may be in the form of a semiconductor wafer 205. In some examples, the substrate 204 has a thickness in a range of about 100 μm to about 1000 μm.

The wide bandgap epitaxial layer 202 may be formed by epitaxial growth. The wide bandgap epitaxial layer 202 may be, in some embodiments, a silicon carbide epitaxial layer. The wide bandgap epitaxial layer 202 may be, in some embodiments, a Group III-nitride. The wide bandgap epitaxial layer 202 may be formed using any suitable epitaxial growth process, such as hybrid vapor phase epitaxy (HVPE), metal-organic vapor phase epitaxy (MOVPE), molecular beam epitaxy (MBE), or other suitable growth process. The wide bandgap epitaxial layer 202 may have a thickness in a range of about 0.2 μm to about 200 μm, such as about 0.5 μm to about 100 μm, such as about 0.5 μm to about 20 μm.

In some examples, the substrate 204 may include a buffer layer 206. The buffer layer may be an epitaxial layer. The buffer layer 206 may be formed by epitaxial growth on the substrate 204. The buffer layer 206 may be used to mitigate a lattice mismatch between, for instance, the first substrate 204 (e.g., sapphire substrate) and the wide bandgap epitaxial layer 202. In some embodiments, the buffer layer 206 may be a Group III-nitride, such as aluminum nitride.

The method 200 may include at 220 fabricating one or more semiconductor device structures (e.g., transistor structures, Schottky diode structures, etc.) at least in part in the wide bandgap epitaxial layer 202. More particularly, one or more semiconductor device structures (e.g., MOSFETs, Schottky diodes, HEMTs) may be fabricated in the wide bandgap epitaxial layer 202.

For purposes of illustration and discussion, fabricating one or more semiconductor device structures may include forming one or more doped regions 212 in the wide bandgap epitaxial layer 202. The one or more doped regions may include regions of a first conductivity type (e.g., n-type) and may include regions of a second conductivity type (e.g., p-type). In some embodiments, the one or more doped regions may be formed, for instance, by dopant implantation. In some embodiments, the one or more doped regions may be formed, for instance, as part of epitaxial growth of the wide bandgap epitaxial layer 202.

Fabricating one or more semiconductor device structures may include forming one or more contacts 214 (e.g., metal contacts) on the wide bandgap epitaxial layer 202. For instance, polysilicon and/or metal deposition techniques may be used to form patterned contacts 214 on the wide bandgap epitaxial layer 202. The contacts 214 may include, in some embodiments, a source contact, a drain contact, and a gate contact on the surface of the wide bandgap epitaxial layer 202. The contacts 214 may include, for instance, solder bumps, contact pads, or other interconnect structures on the wide bandgap epitaxial layer 202.

Fabricating one or more semiconductor device structures may include other fabrication steps, such as deposition steps, etching steps, metallization steps, etc. The description of the fabrication process has been simplified in this discussion of FIG. 2 for purposes of illustration and discussion. Those of ordinary skill in the art, using the disclosures provided herein, will understand that any suitable fabrication process(s) may be used to form semiconductor device structures in the wide bandgap epitaxial layer 202 without deviating from the scope of the present disclosure.

Referring to FIG. 2, the method 200 at 230 may include “flipping” the semiconductor wafer 205 and attaching the semiconductor wafer 205 to submount(s) 222. The submount 222 may include, for instance, a lead frame(s), a heat sink(s), clip structure(s), DBC substrate(s), or other suitable submount(s). The contacts 214 may be attached to metal structures 224 (e.g., pads) on the submount(s) to provide thermal and/or electrical connections to the contacts 214. In some embodiments, a die-attach material may be used to attach the wafer 205 to the submount(s) 222.

Referring to FIG. 2 at 240, the method 200 may include removing the substrate 204 (e.g., the sapphire substrate) from the wide bandgap epitaxial layer 202. The removal process at 240 is implemented by a backside processing tool 264. The backside processing tool 264 may implement a process 262 such as a CMP process or grinding process to remove the backside of the wafer 205, including some or all of the substrate 204.

Once the substrate 204 has been removed from the wide bandgap epitaxial layer 202, the method 200 at 250 yields an assembly 245 with semiconductor die (without a substrate) including the wide bandgap epitaxial layer 202 attached to the submount(s) 222. The assembly 245 may be singulated or diced and processed to form individual semiconductor device packages including one or more semiconductor die.

For instance, at 260, the method 200 may include providing an insulating material 255 on the wide bandgap epitaxial layer 202 and the submount 222 to form a power semiconductor device package 250. The insulating material 255 may be an epoxy mold compound. The method 200 may further include providing an underfill material 257 on the contacts 214. The underfill material 257 may be, for instance, a composite material made up of a polymer (e.g., epoxy polymer) with filler and/or additional components. The underfill material 257 may increase creepage between, for instance, a source contact and a gate contact for the power semiconductor package 250. The power semiconductor device package 250 may be a discrete power semiconductor package. However, in some embodiments, the power semiconductor device package may be, for instance, a power module.

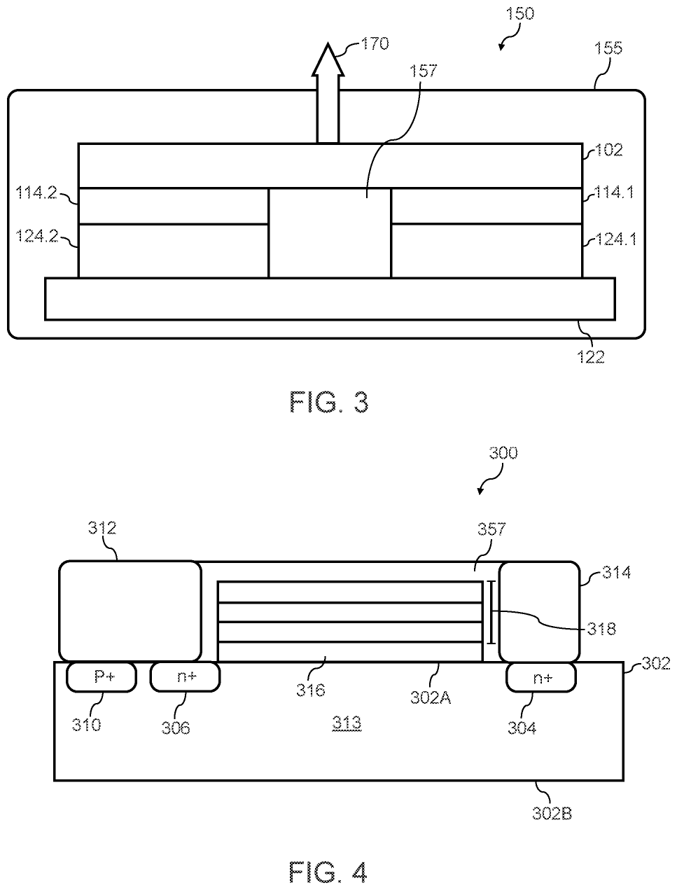

FIG. 3 depicts a cross-sectional view of a portion of an example semiconductor device package 150 according to example embodiments of the present disclosure, such as a semiconductor device package fabricated using the method of FIG. 1. The semiconductor device package 150 includes the wide bandgap epitaxial layer 102. The wide bandgap epitaxial layer 102 may include one or more semiconductor devices, such as MOSFETs, diodes, HEMTs, etc. The wide bandgap epitaxial layer 102 may be silicon carbide in some embodiments. The wide bandgap epitaxial layer 102 may be a Group III-nitride in some embodiments.

The wide bandgap epitaxial layer 102 may be attached to a submount 122. The submount 122 may be a lead frame, a power substrate, DBC substrate, AMB substrate, a clip structure, or other suitable submount. The submount 122 may include contact portions (e.g., metal pads) 124.1 and 124.2. Contacts (e.g., metal contacts) 114.1 and 114.2 on the wide bandgap epitaxial layer 102 may be attached or coupled to the contact portions 124.1 and 124.2 respectively (e.g., using a die-attach material). The contacts 114.1 and 114.2 may include solder bumps or other suitable attach structures. The contact portions 124.1 and 124.2 may include conductive pads (e.g., copper pads). In some examples, the contact 114.1 may be a source contact and the contact 114.2 may be a drain contact. The wide bandgap epitaxial layer 102 may further include a gate contact (not illustrated). In this way, the wide bandgap epitaxial layer 102 includes one or more lateral power semiconductor devices. The semiconductor device package 150 may include an underfill material 157. The underfill material 157 may be between the contact 114.1 and contact 114.2. The underfill material 157 may be, for instance, a composite material made up of a polymer (e.g., epoxy polymer) with filler and/or additional components. In some examples, the underfill material 157 may also be between contact portions 124.1 and 124.2 on the submount 122. The underfill material 157 may provide creepage between the contacts 114.1 and 114.2. In other words, the underfill material 157 may act an insulating material between the contacts 114.1 and 114.2 to prevent leakage or breakdown between the contacts 114.1 and 114.2 The underfill material 157 may be applied prior to or after the contacts 114.1 and 114.2 are attached to the contact portions 124.1 and 124.2.

The semiconductor device package 150 includes an insulating material 155 on the wide bandgap epitaxial layer 102. The insulating material 155 may be an epoxy mold compound. The insulating material 155 may form the housing for the semiconductor device package 150. The insulating material 155 may directly contact the wide bandgap epitaxial layer 102.

The wide bandgap epitaxial layer 102 is not in direct or indirect contact with a silicon carbide substrate. Arrow 170 depicts a conductive heat path for the transfer of heat from the wide bandgap epitaxial layer 102. As shown, the conductive heat path indicated by arrow 170 does not include a silicon carbide substrate. Indeed, the conductive heat path indicated by arrow 170 does not include a semiconductor substrate.

FIG. 4 depicts a cross-sectional view of an example lateral transistor device 300 that may be fabricated based at least in part from wide bandgap epitaxial layer 302 without a silicon carbide substrate according to example embodiments of the present disclosure. The wide bandgap epitaxial layer 302 may be similar to any of the wide bandgap epitaxial layers described herein. The wide bandgap epitaxial layer 302 may have a thickness in a range of about 0.2 μm to about 200 μm, such as about 0.5 μm to about 100 μm, such as about 0.5 μm to about 20 μm.

The lateral transistor device 300 may include a wide bandgap epitaxial layer 302 (e.g., epitaxial silicon carbide layer) having a first surface 302A and an opposing second surface 302B. The lateral transistor device 300 may include a source contact 312, a drain contact 314, and a gate contact 318 on the first surface 302A of the wide bandgap epitaxial layer 302 such that the transistor device 300 is a lateral device. The second surface 302B of the epitaxial silicon carbide layer may be free from contact with a silicon carbide substrate. In some examples, the epitaxial silicon carbide layer is on a sapphire substrate (not shown). In some examples, the epitaxial silicon carbide layer is on a silicon substrate (not shown). In some examples, there is no semiconductor substrate.

In some examples, the lateral transistor device 300 is a MOSFET. The wide bandgap epitaxial layer 302 may include a drift region 313 having a first conductivity type (e.g., n-type). The drift region 313 may be an n-region. At least a portion of the drift region 313 is in the wide bandgap epitaxial layer 302 (E.g., epitaxial silicon carbide layer) between the source contact 312 and the drain contact 314. The wide bandgap epitaxial layer 302 may include a well region 310 of a second conductivity type (e.g., p-type). The well-region 310 may be a p+ region. The well region 310 may be in the epitaxial wide bandgap semiconductor structure 302 between the drift region 313 and the source contact 312.

In some examples, the wide bandgap epitaxial layer 302 includes a source region 306 of the first conductivity type (e.g., n-type). The source region 306 may be an n+ region. The source region 306 may be in the wide bandgap epitaxial layer 302 proximate to the source contact 312. In some examples, the wide bandgap epitaxial layer 302 includes a drain region 304 of the first conductivity type (e.g., n-type). The drain region 304 may be an n+ region. The drain region 304 may be in the wide bandgap epitaxial layer 302 proximate to the drain contact 314.

In some examples, the source contact 312 and the drain contact 314 are each ohmic contacts with the wide bandgap epitaxial layer 302. For instance, the source contact 312 and the drain contact 314 may each include a nickel-based conductive layer, such as Ni and/or NiSi. Other suitable metals capable of making an ohmic contact with the wide bandgap epitaxial layer 302 may be used without deviating from the scope of the present disclosure.

In some examples, the gate contact 318 may be on the first surface 302A of the wide bandgap epitaxial layer 302. The gate contact 318 may be a multilayer gate contact 318 in some embodiments. The multilayer gate contact 318 may include, for instance, one or more polysilicon layers, one or more metal layers, one or more inter metal dielectric (IMD) layers, etc. The transistor device 300 includes a gate dielectric 316 between the gate contact 318 and the wide bandgap epitaxial layer 302. The gate dielectric 316 may be, for instance, an oxide, such as silicon dioxide.

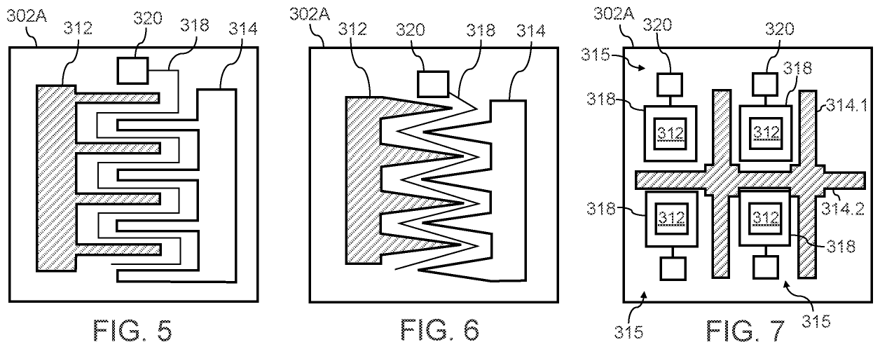

Due to the lateral nature of the transistor device 300, the source contact 312, the drain contact 314, and the gate contact 318 may be provided in various patterns on the first surface 302A of the wide bandgap epitaxial layer 302. FIGS. 5-7 depict example contact patterns on a surface 302A of the wide bandgap semiconductor layer 302.

An underfill material 357 may be between the source contact 312 and the drain contact 314. The underfill material 357 may be, for instance, a composite material made up of a polymer (e.g., epoxy polymer) with filler and/or additional components. The underfill material 357 may provide creepage between the source contact 312 and the drain contact 314. In other words, the underfill material 357 may act an insulating material between the source contact 312 and the drain contact 314 to prevent leakage or breakdown between the source contact 312 and the drain contact 314.

In the description above it is assumed that the transistor device 300 is an n-type power MOSFET. However, those of ordinary skill in the art, using the disclosures provided herein, will understand that aspects of the present disclosure may be implement in a p-type power MOSFET or other semiconductor device (e.g., IGBT, Schottky diode, etc.) without deviating from the scope of the present disclosure.

For example, FIG. 5 depicts an example source contact 312, drain contact 314, and gate contact 318 on the surface 302A of the wide bandgap semiconductor layer 302. A gate pad 320 may be an electrical connection to the gate contact 318. The gate contact 318 is between the source contact 312 and the drain contact 314. The source contact 312 and the drain contact 314 are interdigitated with one another. For instance, each of the source contact 312 and the drain contact 314 have a comb-like pattern. Fingers of the comb-like pattern of the source contact 312 are interdigitated with fingers of the comb-like pattern of the drain contact 314.

FIG. 6 depicts an example source contact 312, drain contact 314, and gate contact 318 on the surface 302A of the wide bandgap semiconductor layer 302. A gate pad 320 may be an electrical connection to the gate contact 318. The gate contact 318 is between the source contact 312 and the drain contact 314. Similar to FIG. 5, the source contact 312 and the drain contact 314 are interdigitated with one another. For instance, each of the source contact 312 and the drain contact 314 have a comb-like pattern. Fingers of the comb-like pattern of the source contact 312 are triangular in shape. Fingers of the comb-like pattern of the drain contact 314 are triangular in shape. Fingers of the comb-like pattern of the source contact 312 are interdigitated with fingers of the comb-like pattern of the drain contact 314.

FIG. 7 an example source contact 312, drain contact 314, and gate contact 318 on the surface 302A of the wide bandgap semiconductor layer 302. The drain contacts 312 may include a plurality of intersecting drain buses 312.1, 312.2, . . . , 312.n forming a grid pattern. The drain contact 314 may include a plurality of drain contacts 314 that may be located within spaces 315 formed in the grid pattern. The gate contact 318 may include a plurality of gate contacts 318 with gate pads 320 providing electrical connections for the gate contacts 318. Each gate contact 318 at least partially surrounds one of the plurality of drain contacts 314 in a space 315 in the grid pattern formed by the source contact 312.

FIGS. 5-7 depicts example patterns of source contacts 312, drain contacts 314, and gate contacts 318 for purposes of illustration and discussion. Other patterns may be used without deviating from the scope of the present disclosure.

In some examples, the methods according to example aspects of the present disclosure may not include removing a substrate from the epitaxial wide bandgap epitaxial layer. The substrate may remain. The substrate may not include silicon carbide. For instance, the substrate may be a sapphire substrate or a silicon substrate.

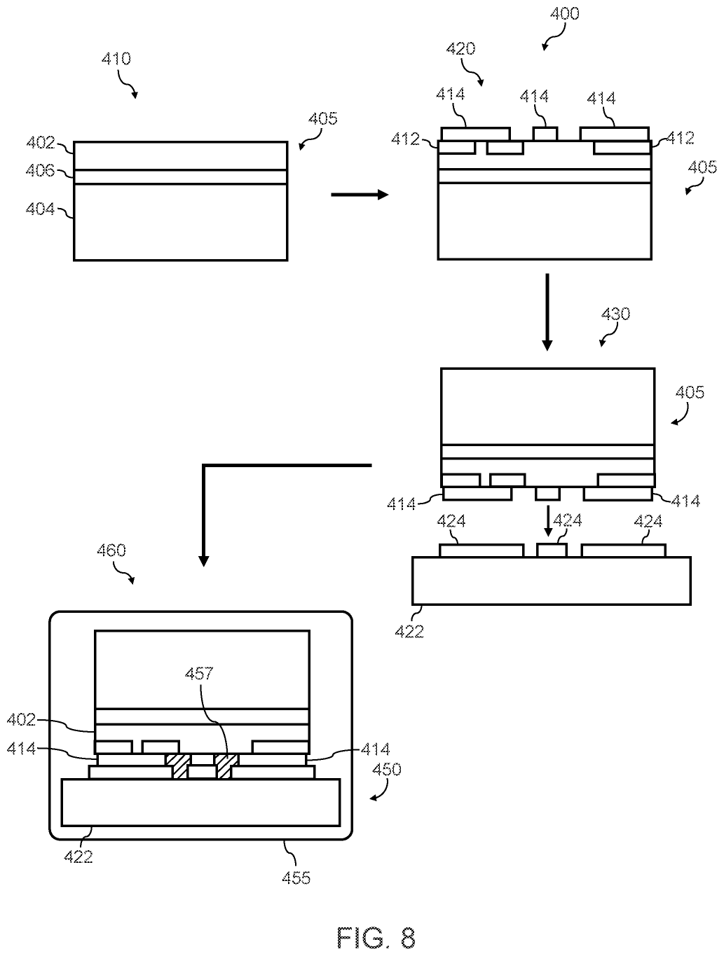

For example, FIG. 8 depicts an overview of an example method 400 according to example embodiments of the present disclosure. FIG. 8 is intended to represent structures for identification and description and is not intended to represent the structures to physical scale. The method 400 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

The method 400 is similar to the method 100 of FIG. 1. However, at 410, the method 400 may include providing a wide bandgap epitaxial layer 402 on a substrate 404. The substrate 404 does not include silicon carbide. The substrate 404 may be a sapphire substrate, or silicon substrate in some examples. The substrate 404 may be in the form of a semiconductor wafer 405. In some examples, the substrate 404 has a thickness in a range of about 100 μm to about 1000 μm.

The wide bandgap epitaxial layer 402 may be formed by epitaxial growth. The wide bandgap epitaxial layer 402 may be, in some embodiments, a silicon carbide epitaxial layer. The wide bandgap epitaxial layer 402 may be, in some embodiments, a Group III-nitride. The wide bandgap epitaxial layer 402 may be formed using any suitable epitaxial growth process, such as hybrid vapor phase epitaxy (HVPE), metal-organic vapor phase epitaxy (MOVPE), molecular beam epitaxy (MBE), or other suitable growth processes. The wide bandgap epitaxial layer 402 may have a thickness in a range of about 0.2 μm to about 200 μm, such as about 0.5 μm to about 100 μm, such as about 0.5 μm to about 20 μm.

In some examples, the substrate 404 may include a buffer layer 406. The buffer layer may be an epitaxial layer. The buffer layer 406 may be formed by epitaxial growth on the substrate 404. The buffer layer 406 may be used to mitigate a lattice mismatch between, for instance, the first substrate 404 (e.g., sapphire substrate) and the wide bandgap epitaxial layer 402. In some embodiments, the buffer layer 406 may be a Group III-nitride, such as aluminum nitride.

The method 400 may include at 420 fabricating one or more semiconductor device structures (e.g., transistor structures, Schottky diode structures, etc.) at least in part in the wide bandgap epitaxial layer 402. More particularly, one or more semiconductor device structures (e.g., MOSFETs, Schottky diodes, HEMTs) may be fabricated in the wide bandgap epitaxial layer.

For purposes of illustration and discussion, fabricating one or more semiconductor device structures may include forming one or more doped regions 412 in the wide bandgap epitaxial region. The one or more doped regions may include regions of a first conductivity type (e.g., n-type) and may include regions of a second conductivity type (e.g., p-type). In some embodiments, the one or more doped regions may be formed, for instance, by dopant implantation. In some embodiments, the one or more doped regions may be formed, for instance, as part of epitaxial growth of the wide bandgap epitaxial layer 402.

Fabricating one or more semiconductor device structures may include forming one or more contacts 414 (e.g., metal contacts) on the wide bandgap epitaxial layer 402. For instance, polysilicon and/or metal deposition techniques may be used to form patterned contacts 414 on the wide bandgap epitaxial layer 402. The contacts 414 may include, in some embodiments, a source contact, a drain contact, and a gate contact on the surface of the wide bandgap epitaxial layer 402. The contacts 414 may include, for instance, solder bumps, contact pads, or other interconnect structures on the wide bandgap epitaxial layer 402.

Fabricating one or more semiconductor device structures may include other fabrication steps, such as deposition steps, etching steps, metallization steps, etc. The description of the fabrication process has been simplified in this discussion of FIG. 8 for purposes of illustration and discussion. Those of ordinary skill in the art, using the disclosures provided herein, will understand that any suitable fabrication process(s) may be used to form semiconductor device structures in the wide bandgap epitaxial layer 102 without deviating from the scope of the present disclosure.

Referring to FIG. 8, the method 400 at 430 may include “flipping” the semiconductor wafer 405 and attaching the semiconductor wafer 405 to submount(s) 422. The submount 422 may include, for instance, a lead frame(s), a heat sink(s), clip structure(s), DBC substrate(s), or other suitable submount(s). The contacts 414 may be attached to metal structures 424 (e.g., pads) on the submount(s) to provide thermal and/or electrical connections to the contacts 414. In some embodiments, a die-attach material may be used to attach the wafer 405 to the submount(s) 422.

The method of FIG. 8 does not include removing the substrate from the wide bandgap epitaxial layer 402. Rather, the method 400 moves directly to 460, where the method 400 may include providing an insulating material 455 on the wide bandgap epitaxial layer 402 and the submount 422 to form a power semiconductor device package 450. The insulating material 455 may be an epoxy mold compound. The method 400 may further include providing an underfill material 457 on the contacts 414. The underfill material 457 may be, for instance, a composite material made up of a polymer (e.g., epoxy polymer) with filler and/or additional components. The underfill material 457 may increase creepage between, for instance, a source contact and a gate contact for the power semiconductor package 450. The power semiconductor device package 450 may be a discrete power semiconductor package. However, in some embodiments, the power semiconductor device package may be, for instance, a power module.

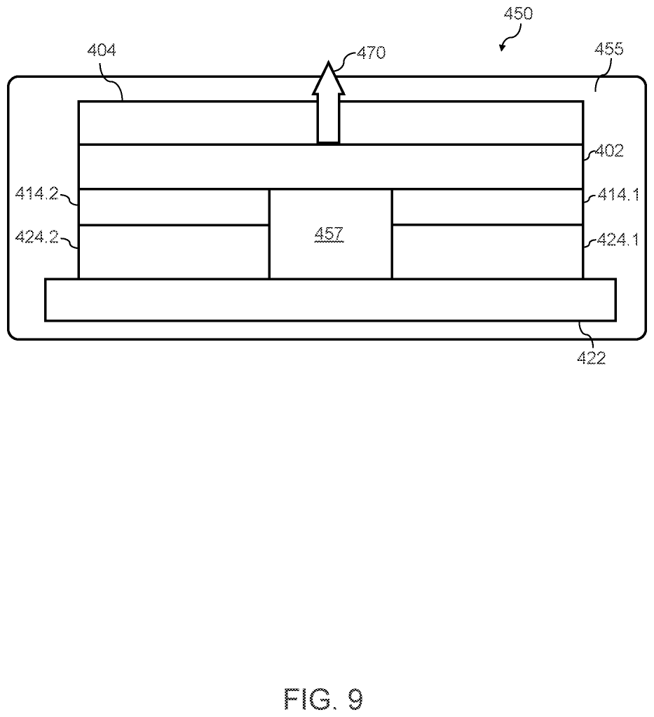

FIG. 9 depicts a cross-sectional view of a portion of an example semiconductor device package 450 according to example embodiments of the present disclosure. The semiconductor device package 450 includes the wide bandgap epitaxial layer 402. The wide bandgap epitaxial layer 402 may include one or more semiconductor devices, such as MOSFETs, diodes, HEMTs, etc. The wide bandgap epitaxial layer 402 may be silicon carbide in some embodiments. The wide bandgap epitaxial layer 402 may be a Group III-nitride in some embodiments.

The wide bandgap epitaxial layer 402 may be attached to a submount 422. The submount 422 may be a lead frame, a power substrate, a DBC substrate, an AMB substrate, a clip structure, or other suitable submount. The submount 422 may include contact portions (e.g., metal pads) 424.1 and 424.2. Contacts (e.g., metal contacts) 414.1 and 414.2 on the wide bandgap epitaxial layer 402 may be attached or coupled to the contact portions 424.1 and 424.2 respectively (e.g., using a die-attach material). In some examples, the contact 414.1 may be a source contact and the contact 414.2 may be a drain contact. The wide bandgap epitaxial layer 402 may further include a gate contact (not illustrated). In this way, the wide bandgap epitaxial layer 402 includes one or more lateral power semiconductor device.

The semiconductor device package 450 may include an underfill material 457. The underfill material 457 may be between the contact 414.1 and contact 414.2 (to provide creepage). In some examples, the underfill material 457 may also be between contact portions 424.1 and 424.2 on the submount 422.

The semiconductor device package 450 includes an insulating material 455 on the wide bandgap epitaxial layer 402. The insulating material 455 may be an epoxy mold compound. The insulating material 455 may form the housing for the semiconductor device package 450. The insulating material 455 may be directly on the substrate 404.

The wide bandgap epitaxial layer 402 is not in direct or indirect contact with a silicon carbide substrate. Arrow 470 depicts a conductive heat path for the transfer of heat from the wide bandgap epitaxial layer 402. As shown, the conductive heat path indicated by arrow 470 does not include a silicon carbide substrate. Rather, the conductive heat path indicated by arrow 470 passes through the substrate 404 that does not include silicon carbide. The conductive heat path indicated by arrow 470 may pass through a substrate 404 that is a sapphire substrate or a silicon substrate.

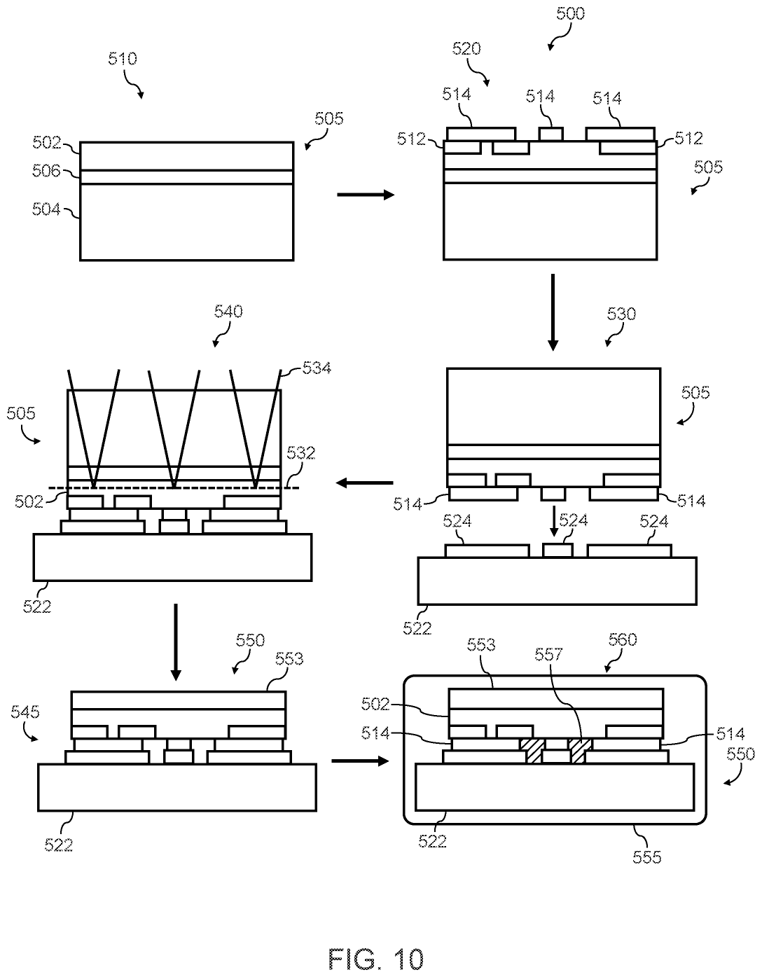

The methods according to example embodiments of the present disclosure may also be used to fabricate vertical power semiconductor devices. FIG. 10 depicts an overview of an example method 500 according to example embodiments of the present disclosure. FIG. 10 is intended to represent structures for identification and description and is not intended to represent the structures to physical scale. The method 300 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 510, the method may include providing a wide bandgap epitaxial layer 502 on a substrate 504. The substrate 504 may be a silicon carbide substrate (e.g., 4H monocrystalline silicon carbide), sapphire substrate, or silicon substrate in some examples. Other suitable substrates may be used like the substrate 504 without deviating from the scope of the present disclosure. The substrate 504 may be in the form of a semiconductor wafer 505. In some examples, the substrate 504 has a thickness in a range of about 100 μm to about 1000 μm.

The wide bandgap epitaxial layer 502 may be formed by epitaxial growth. The wide bandgap epitaxial layer 502 may be, in some embodiments, a silicon carbide epitaxial layer. The wide bandgap epitaxial layer 502 may be, in some embodiments, a Group III-nitride. The wide bandgap epitaxial layer 502 may be formed using any suitable epitaxial growth process, such as hybrid vapor phase epitaxy (HVPE), metal-organic vapor phase epitaxy (MOVPE), molecular beam epitaxy (MBE), or other suitable growth process. The wide bandgap epitaxial layer 502 may have a thickness in a range of about 0.2 μm to about 200 μm, such as about 0.5 μm to about 100 μm, such as about 0.5 μm to about 20 μm.

In some examples, the substrate 504 may include a buffer layer 506. The buffer layer may be an epitaxial layer. The buffer layer 506 may be formed by epitaxial growth on the substrate 504. The buffer layer 506 may be used to mitigate a lattice mismatch between, for instance, the substrate 504 (e.g., sapphire substrate) and the wide bandgap epitaxial layer 502. In some embodiments, the buffer layer 506 may be a Group III-nitride, such as aluminum nitride.

The method 500 may include at 520 fabricating one or more semiconductor device structures (e.g., transistor structures, Schottky diode structures, etc.) at least in part in the wide bandgap epitaxial layer 502. More particularly, one or more semiconductor device structures (e.g., MOSFETs, Schottky diodes, HEMTs) may be fabricated in the wide bandgap epitaxial layer.

For purposes of illustration and discussion, fabricating one or more semiconductor device structures may include forming one or more doped regions 512 in the wide bandgap epitaxial region. The one or more doped regions may include regions of a first conductivity type (e.g., n-type) and may include regions of a second conductivity type (e.g., p-type). In some embodiments, the one or more doped regions may be formed, for instance, by dopant implantation. In some embodiments, the one or more doped regions may be formed, for instance, as part of epitaxial growth of the wide bandgap epitaxial layer 502.

Fabricating one or more semiconductor device structures may include forming one or more contacts 514 (e.g., metal contacts) on the wide bandgap epitaxial layer 502. For instance, polysilicon and/or metal deposition techniques may be used to form patterned contacts 514 on the wide bandgap epitaxial layer. The contacts 514 may include, in some embodiments, a source contact, a drain contact, and a gate contact on the surface of the wide bandgap epitaxial layer 502. The contacts 514 may include, for instance, solder bumps, contact pads, or other interconnect structures on the wide bandgap epitaxial layer 502.

Fabricating one or more semiconductor device structures may include other fabrication steps, such as deposition steps, etching steps, metallization steps, etc. The description of the fabrication process has been simplified in this discussion of FIG. 10 for purposes of illustration and discussion. Those of ordinary skill in the art, using the disclosures provided herein, will understand that any suitable fabrication process(s) may be used to form semiconductor device structures in the wide bandgap epitaxial layer 502 without deviating from the scope of the present disclosure.

Referring to FIG. 10, the method 500 at 530 may include “flipping” the semiconductor wafer 505 and attaching the semiconductor wafer 505 to submount(s) 522. The submount 522 may include, for instance, a lead frame(s), a heat sink(s), clip structure(s), DBC substrate(s), or other suitable submount(s). The contacts 514 may be attached to metal structures 524 (e.g., pads) on the submount(s) to provide thermal and/or electrical connections to the contacts 114. In some embodiments, a die-attach material may be used to attach the wafer 505 to the submount(s) 522.

Referring to FIG. 10 at 540, the method 500 may include removing the substrate 504 (e.g., the sapphire substrate) from the wide bandgap epitaxial layer 502. One example removal process may include inducing a cleavage plane 532 in the wide bandgap epitaxial layer 502 and removing the first substrate 504 from the wide bandgap epitaxial layer 502 along the cleavage plane 532. Inducing the cleavage plane 532 may include emitting one or more lasers 534 into the wide bandgap epitaxial layer 502 to induce damaged regions along the cleavage plane 532. Other suitable techniques may be used to induce the cleavage plane 532 without deviating from the scope of the present disclosure, such as implanting one or more species into the wide bandgap epitaxial layer 502. In some embodiments, the removal process at 530 may be implemented by a backside processing tool. The backside processing tool may implement a process such as a CMP process or grinding process to remove the backside of the wafer 505, including some or all of the substrate 504. In some embodiments, an etching process may be used to remove the backside of the wafer 505, including some or all of the substrate 504.

Once the substrate 504 has been removed from the wide bandgap epitaxial layer 502, the method 500 at 550 yields an assembly 545 with semiconductor die (without a substrate) including the wide bandgap epitaxial layer 502 attached to the submount(s) 522. A backside contact 553 (e.g., metal layer) may be provided on the wide bandgap epitaxial layer 502. The backside contact 553 may be formed using any suitable metallization process such as metal deposition process, sputtering process, etc. The assembly 545 may be singulated or diced and processed to form individual semiconductor device packages including one or more semiconductor die.

For instance, at 560, the method 500 may include providing an insulating material 555 on the wide bandgap epitaxial layer 502 and the submount 522 to form a power semiconductor device package 550. The insulating material 555 may be an epoxy mold compound. The method 500 may further include providing an underfill material 557 on the contacts 514. The underfill material 557 may be, for instance, a composite material made up of a polymer (e.g., epoxy polymer) with filler and/or additional components. The underfill material 557 may increase creepage between, for instance, a source contact and a gate contact for the power semiconductor package 550. The power semiconductor device package 550 may be a discrete power semiconductor package. However, in some embodiments, the power semiconductor device package may be, for instance, a power module.

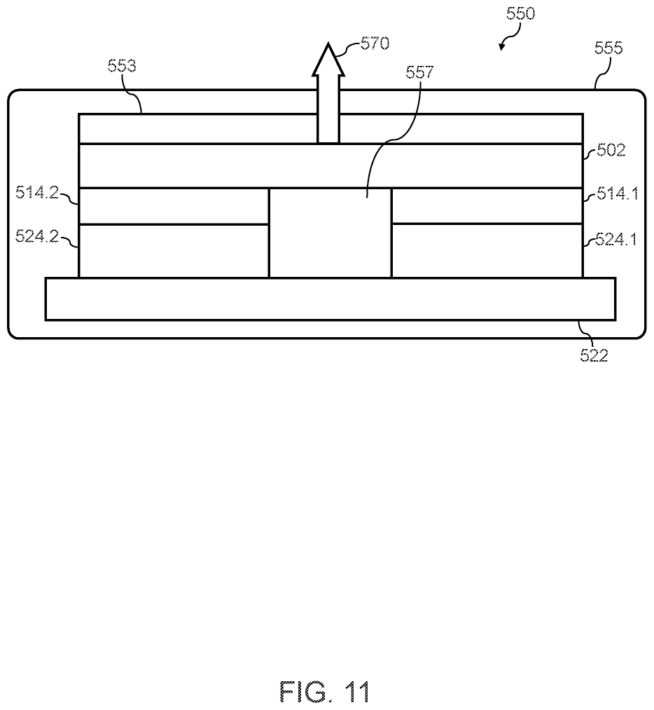

FIG. 11 depicts a cross-sectional view of a portion of an example semiconductor device package 550 according to example embodiments of the present disclosure. The semiconductor device package 550 includes the wide bandgap epitaxial layer 502. The wide bandgap epitaxial layer 502 may include one or more semiconductor devices, such as MOSFETs, diodes, HEMTs, etc. The wide bandgap epitaxial layer 502 may be silicon carbide in some embodiments. The wide bandgap epitaxial layer 502 may be a Group III-nitride in some embodiments.

The wide bandgap epitaxial layer 502 may be attached to a submount 522. The submount 522 may be a lead frame, a DBC substrate, a clip structure, or other suitable submount. The submount 522 may include contact portions (e.g., metal pads) 524.1 and 524.2. Contacts (e.g., metal contacts) 514.1 and 514.2 on the wide bandgap epitaxial layer 502 may be attached or coupled to the contact portions 524.1 and 524.2 respectively (e.g., using a die-attach material). In some examples, the contact 514.1 may be a source contact and the contact 514.2 may be a drain contact. The wide bandgap epitaxial layer 502 may further include a gate contact (not illustrated). In this way, the wide bandgap epitaxial layer 502 includes one or more lateral power semiconductor devices.

The semiconductor device package 550 may include an underfill material 557. The underfill material 557 may be between the contact 514.1 and contact 514.2. The underfill material 557 may be, for instance, a composite material made up of a polymer (e.g., epoxy polymer) with filler and/or additional components. In some examples, the underfill material 557 may also be between contact portions 524.1 and 524.2 on the submount 522. The underfill material 557 may provide creepage between the contacts 514.1 and 514.2. In other words, the underfill material 157 may act an insulating material between the contacts 514.1 and 514.2 to prevent leakage or breakdown between the contacts 514.1 and 514.2 The underfill material 557 may be applied prior to or after the contacts 514.1 and 514.2 are attached to the contact portions 524.1 and 524.2.

The semiconductor device package 550 includes an insulating material 555 on the wide bandgap epitaxial layer 502. The insulating material 555 may be an epoxy mold compound. The insulating material 555 may form the housing for the semiconductor device package 550. The insulating material 555 may be directly on a backside contact 553.

The wide bandgap epitaxial layer 502 is not in direct or indirect contact with a silicon carbide substrate. Arrow 570 depicts a conductive heat path for the transfer of heat from the wide bandgap epitaxial layer 502. As shown, the conductive heat path indicated by arrow 570 does not include a silicon carbide substrate. Rather, the conductive heat path indicated by arrow 570 passes through the backside contact 553.

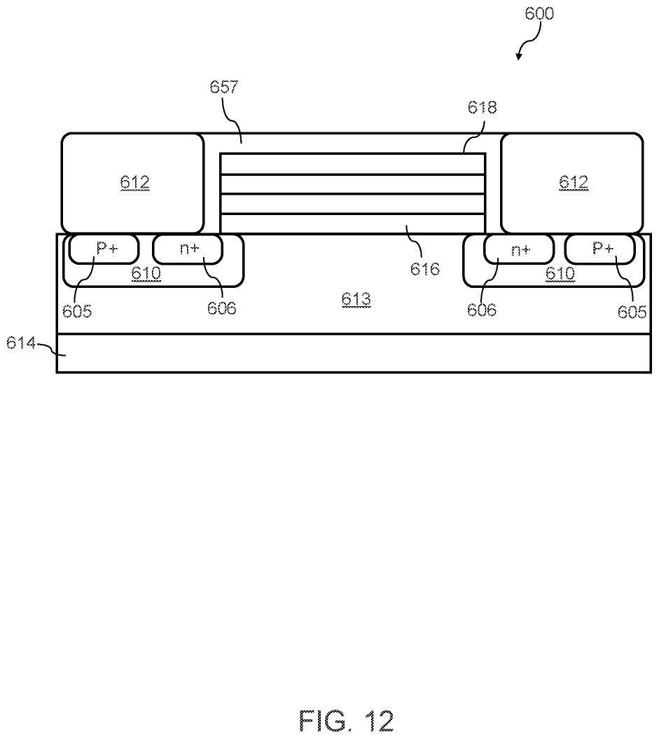

FIG. 12 depicts a cross-sectional view of an example vertical transistor device 600 that may be fabricated based at least in part from wide bandgap epitaxial layer 602 without a silicon carbide substrate according to example embodiments of the present disclosure. The wide bandgap epitaxial layer 602 may be similar to any of the wide bandgap epitaxial layers described herein. The wide bandgap epitaxial layer 602 may have a thickness in a range of about 0.2 μm to about 200 μm, such as about 0.5 μm to about 100 μm, such as about 0.5 μm to about 20 μm.

The wide bandgap epitaxial layer 302 (e.g., epitaxial silicon carbide layer) may have a first surface 602A and an opposing second surface 602B. The vertical transistor device 600 may include source contact(s) 612 on the first surface 602A. The vertical transistor device 600 may include a drain contact 614 on the second surface 602B. The vertical transistor device 600 may include a gate contact 618 on the first surface 602A of the wide bandgap epitaxial layer 602 such that the transistor device 600.

The second surface 602B of the epitaxial silicon carbide layer may be free from contact with a silicon carbide substrate. In some examples, the epitaxial silicon carbide layer is on a sapphire substrate (not shown). In some examples, the epitaxial silicon carbide layer is on a silicon substrate (not shown). In some examples, there is no semiconductor substrate.

In some examples, the lateral transistor device 600 is a MOSFET. The wide bandgap epitaxial layer 602 may include a drift region 613 having a first conductivity type (e.g., n-type). The drift region 613 may be an n-type region. At least a portion of the drift region 613 is in the wide bandgap epitaxial layer 602 (e.g., epitaxial silicon carbide layer) between the source contacts 612 and under the gate contact 618. The wide bandgap epitaxial layer 602 may include a deep well region 610 of a second conductivity type (e.g., p-type) under each source contact 612.

The wide bandgap epitaxial layer 602 may include a base region 605 and a source region 606 under the source contacts 612. The base region 605 may be of a second conductivity type. In some examples, the base region 605 is a p+ region. The source region 606 may be of the first conductivity type (e.g., n-type). The source region 606 may be an n+ region. The source region 606 may be in the wide bandgap epitaxial layer 602 proximate to the source contact 612.

In some examples, the source contact 612 and the drain contact 314 are each ohmic contacts with the wide bandgap epitaxial layer 602. For instance, the source contact 612 and the drain contact 614 may each include a nickel-based conductive layer, such as Ni and/or NiSi. Other suitable metals capable of making an ohmic contact with the wide bandgap epitaxial layer 602 may be used without deviating from the scope of the present disclosure.

In some examples, the gate contact 618 may be on the first surface 602A of the wide bandgap epitaxial layer 602. The gate contact 618 may be a multilayer gate contact 618 in some embodiments. The multilayer gate contact 618 may include, for instance, one or more polysilicon layers, one or more metal layers, one or more inter metal dielectric (IMD) layers, etc. The transistor device 600 includes a gate dielectric 616 between the gate contact 618 and the wide bandgap epitaxial layer 602. The gate dielectric 616 may be, for instance, an oxide, such as silicon dioxide.

An underfill material 657 may be between the source contacts 612 and on the gate contact 618. The underfill material 657 may be, for instance, a composite material made up of a polymer (e.g., epoxy polymer) with filler and/or additional components. The underfill material 657 may be an insulator between the different source contacts 612 and between the source contacts 612 and the gate contact 618.

In the description above it is assumed that the transistor device 600 is an n-type power MOSFET. However, those of ordinary skill in the art, using the disclosures provided herein, will understand that aspects of the present disclosure may be implement in a p-type power MOSFET or other semiconductor device (e.g., IGBT, Schottky diode, etc.) without deviating from the scope of the present disclosure.

Example aspects of the present disclosure are set forth below. Any of the below features or examples may be used in combination with any of the embodiments or features provided in the present disclosure.

One example aspect of the present disclosure is directed to a semiconductor device. The semiconductor device includes a wide bandgap epitaxial layer. The wide bandgap epitaxial layer includes silicon carbide. The wide bandgap epitaxial layer has a first surface and an opposing second surface. The semiconductor device includes a first contact on the first surface of the wide bandgap epitaxial layer. The second surface is not in direct or indirect contact with a silicon carbide substrate.

In some embodiments, the semiconductor device comprises a second contact on the second surface of the wide bandgap epitaxial layer such that the semiconductor device is a vertical power semiconductor device.

In some embodiments, there is no silicon carbide substrate between the wide bandgap epitaxial layer and the second contact.

In some embodiments, there is no semiconductor substrate between the wide bandgap epitaxial layer and the second contact.

In some embodiments, the semiconductor device comprises a second contact on the first surface of the wide bandgap epitaxial layer such that the semiconductor device is a lateral power semiconductor device.

In some embodiments, the wide bandgap epitaxial layer is on a sapphire substrate.

In some embodiments, the wide bandgap epitaxial layer is on a silicon substrate.

In some embodiments, the wide bandgap epitaxial layer is not in contact with any semiconductor substrate.

In some embodiments, the semiconductor device includes a gate contact on the first surface of the wide bandgap epitaxial layer between the first contact and the second contact.

In some embodiments, the semiconductor device includes an underfill material on at least a portion of the wide bandgap epitaxial layer between the first contact and the second contact.

In some embodiments, the wide bandgap epitaxial layer is mounted in a flip chip configuration in a semiconductor device package.

In some embodiments, the wide bandgap epitaxial layer directly contacts an insulating material of the semiconductor device package.

In some embodiments, the wide bandgap epitaxial layer comprises one or more doped regions.

In some embodiments, the wide bandgap epitaxial layer has a thickness in a range of about 0.2 μm to about 200 μm.

In some embodiments, the second surface provides at least a portion of a thermal path for dissipation of heat from the wide bandgap epitaxial layer, wherein the thermal path does not include a silicon carbide substrate.

In some embodiments, the semiconductor device comprises a Schottky diode or MOSFET.

Another example aspect of the present disclosure is directed to a semiconductor device package. The semiconductor device package includes a wide bandgap epitaxial layer. The wide bandgap epitaxial layer has a first surface and an opposing second surface. The semiconductor device package includes a first contact on the first surface of the wide bandgap epitaxial layer. The first surface of the wide bandgap epitaxial layer is mounted in a flip chip configuration on a submount. The second surface of the wide bandgap epitaxial layer provides at least a portion of a thermal path configured to dissipate heat from the wide bandgap epitaxial layer. The thermal path does not include a semiconductor substrate.

In some embodiments, the semiconductor device package comprises a second contact on the second surface of the wide bandgap epitaxial layer such that the semiconductor device is a vertical power semiconductor device.

In some embodiments, there is no semiconductor substrate between the wide bandgap epitaxial layer and the second contact.

In some embodiments, the semiconductor device package comprises a second contact on the first surface of the wide bandgap epitaxial layer such that the semiconductor device is a lateral power semiconductor device.

In some embodiments, the wide bandgap epitaxial layer is not in contact with any semiconductor substrate.

In some embodiments, the semiconductor device includes a gate contact on the first surface of the wide bandgap epitaxial layer between the first contact and the second contact.

In some embodiments, the semiconductor device includes an underfill material on at least a portion of the wide bandgap epitaxial layer between the first contact and the second contact.

In some embodiments, the wide bandgap epitaxial layer comprises one or more doped regions.

In some embodiments, the wide bandgap epitaxial layer has a thickness in a range of about 0.2 μm to about 200 μm.

In some embodiments, the wide bandgap epitaxial layer comprises an epitaxial silicon carbide layer.

In some embodiments, the wide bandgap epitaxial layer comprises an epitaxial Group III-nitride layer.

In some embodiments, the second surface provides at least a portion of a thermal path for dissipation of heat from the wide bandgap epitaxial layer, wherein the thermal path does not include a silicon carbide substrate.

In some embodiments, the submount comprises a lead frame, a clip structure, or a directed bonded copper (DBC) submount.

In some embodiments, an insulating material of a semiconductor package is directly on the second surface of the wide bandgap epitaxial layer.

In some embodiments, the insulating material is an epoxy mold compound.

In some embodiments, the semiconductor device package comprises a Schottky diode or a MOSFET.

Another example aspect of the present disclosure is directed to a lateral silicon carbide-based transistor device. The transistor device includes an epitaxial silicon carbide layer having a first surface and an opposing second surface. The transistor device includes a drain contact, a source contact, and a gate contact on the first surface of the epitaxial silicon carbide layer. The second surface of the epitaxial silicon carbide layer is free from contact with a silicon carbide substrate.

In some embodiments, the epitaxial silicon carbide layer is on a sapphire substrate.

In some embodiments, the epitaxial silicon carbide layer is on a silicon substrate.

In some embodiments, there is no semiconductor substrate.

In some embodiments, the transistor device includes an underfill material on the epitaxial silicon carbide layer to increase creepage between the source contact and the drain contact.

In some embodiments, the underfill material is on the gate contact.

In some embodiments, the epitaxial silicon carbide layer comprises a drift region having a first conductivity type, wherein at least a portion of the drift region is between the source contact and the drain contact.

In some embodiments, the epitaxial silicon carbide layer comprises a well region of a second conductivity type, the well region between the drift region and the source contact.

In some embodiments, the epitaxial silicon carbide layer comprises a source region of the first conductivity type proximate to the source contact, and a drain region of the first conductivity type proximate to the drain contact.

In some embodiments, the source contact and the drain contact are each ohmic contacts with the epitaxial silicon carbide layer.

In some embodiments, the transistor device includes a gate dielectric between the gate contact and the epitaxial silicon carbide layer.

In some embodiments, the second surface provides at least a portion of a thermal path for dissipation of heat from the epitaxial silicon carbide layer, wherein the thermal path does not include a silicon carbide substrate.

In some embodiments, the epitaxial silicon carbide layer has a thickness in a range of about 0.2 μm to about 200 μm.

In some embodiments, the epitaxial silicon carbide layer is mounted in a flip chip configuration in a semiconductor device package.

In some embodiments, an insulating material of a semiconductor package is directly on the second surface of the epitaxial silicon carbide layer.

In some embodiments, the drain contact is at least partially interdigitated with the source contact.

In some embodiments, the drain contact comprises a plurality of intersecting drain buses forming a grid, wherein the source contact comprises a plurality of source contacts within spaces in the grid, wherein the gate contact comprises a plurality of gate contacts, each gate contact at least partially surrounding one of the plurality of source contacts.

Another example aspect of the present disclosure is directed to method. The method includes providing a wide bandgap epitaxial layer on a substrate. The wide bandgap epitaxial layer has a first surface and an opposing second surface. The second surface is on the substrate. The method includes providing a contact on the first surface of the wide bandgap epitaxial layer. The method includes placing the first surface of the wide bandgap epitaxial layer on a submount. The method includes removing the substrate from the second surface of the wide bandgap epitaxial layer.

In some embodiments, the substrate comprises a sapphire substrate.

In some embodiments, the substrate comprises a silicon carbide substrate.

In some embodiments, removing the substrate from the second surface comprises: forming a cleavage plane in the wide bandgap epitaxial layer; and removing the substrate along the cleavage plane.

In some embodiments, forming a cleavage plane comprises emitting one or more lasers into the wide bandgap epitaxial layer.

In some embodiments, forming a cleavage plane comprises implanting one or more species into the wide bandgap epitaxial layer.

In some embodiments, removing the substrate comprising a grinding process, etching process, or chemical mechanical polish (CMP) process.

In some embodiments, the wide bandgap epitaxial layer comprises one or more doped regions.

In some embodiments, the wide bandgap epitaxial layer has a thickness in a range of about 0.2 μm to about 200 μm.

In some embodiments, the substrate has a thickness in a range of about 100 μm to about 1000 μm.

In some embodiments, the wide bandgap epitaxial layer comprises an epitaxial silicon carbide layer.

In some embodiments, the wide bandgap epitaxial layer comprises an epitaxial Group III-nitride layer.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a wide bandgap epitaxial layer, the wide bandgap epitaxial layer comprising silicon carbide, the wide bandgap epitaxial layer having a first surface and an opposing second surface;
a first contact on the first surface of the wide bandgap epitaxial layer; and
wherein the second surface is not in direct or indirect contact with a silicon carbide substrate.

2. The semiconductor device of claim 1, wherein the semiconductor device comprises a second contact on the second surface of the wide bandgap epitaxial layer such that the semiconductor device is a vertical power semiconductor device.

3. The semiconductor device of claim 2, wherein there is no silicon carbide substrate between the wide bandgap epitaxial layer and the second contact.

4. The semiconductor device of claim 2, wherein there is no semiconductor substrate between the wide bandgap epitaxial layer and the second contact.

5. The semiconductor device of claim 1, wherein the semiconductor device comprises a second contact on the first surface of the wide bandgap epitaxial layer such that the semiconductor device is a lateral power semiconductor device.

6. The semiconductor device of claim 5, wherein the wide bandgap epitaxial layer is on a sapphire substrate.

7. The semiconductor device of claim 5, wherein the wide bandgap epitaxial layer is on a silicon substrate.

8. The semiconductor device of claim 5, wherein the wide bandgap epitaxial layer is not in contact with any semiconductor substrate.

9. The semiconductor device of claim 5, further comprising a gate contact on the first surface of the wide bandgap epitaxial layer between the first contact and the second contact.

10. The semiconductor device of claim 5, further comprising an underfill material on at least a portion of the wide bandgap epitaxial layer between the first contact and the second contact.

11. The semiconductor device of claim 1, wherein the wide bandgap epitaxial layer is mounted in a flip chip configuration in a semiconductor device package.

12. The semiconductor device of claim 11, wherein the wide bandgap epitaxial layer directly contacts an insulating material of the semiconductor device package.

13. The semiconductor device of claim 1, wherein the wide bandgap epitaxial layer comprises one or more doped regions.

14. The semiconductor device of claim 1, wherein the wide bandgap epitaxial layer has a thickness in a range of about 0.2 μm to about 200 μm.

15. The semiconductor device of claim 1, wherein the second surface provides at least a portion of a thermal path for dissipation of heat from the wide bandgap epitaxial layer, wherein the thermal path does not include a silicon carbide substrate.

16. The semiconductor device of claim 1, wherein the semiconductor device comprises a Schottky diode or MOSFET.

17. A semiconductor device package, comprising:
a wide bandgap epitaxial layer, the wide bandgap epitaxial layer having a first surface and an opposing second surface;
a first contact on the first surface of the wide bandgap epitaxial layer; and
wherein the first surface of the wide bandgap epitaxial layer is mounted in a flip chip configuration on a submount; and
wherein the second surface of the wide bandgap epitaxial layer provides at least a portion of a thermal path configured to dissipate heat from the wide bandgap epitaxial layer, wherein the thermal path does not include a semiconductor substrate.

18. The semiconductor device package of claim 17, wherein the semiconductor device package comprises a second contact on the second surface of the wide bandgap epitaxial layer such that the semiconductor device is a vertical power semiconductor device, wherein there is no semiconductor substrate between the wide bandgap epitaxial layer and the second contact.

19.-29. (canceled)

30. The semiconductor device package of claim 17, wherein an insulating material of a semiconductor package is directly on the second surface of the wide bandgap epitaxial layer.

31.-49. (canceled)

50. A method, comprising:
providing a wide bandgap epitaxial layer on a substrate, the wide bandgap epitaxial layer having a first surface and an opposing second surface, the second surface being on the substrate;
providing a contact on the first surface of the wide bandgap epitaxial layer,
placing the first surface of the wide bandgap epitaxial layer on a submount; and
removing the substrate from the second surface of the wide bandgap epitaxial layer.

51.-61. (canceled)
